(19) United States
(12) Patent Application Publication
(10) Pub. No.: US 2025/0251358 A1
(43) Pub. Date: Aug. 7, 2025

(54) OIL STATE DETECTION APPARATUS

(71) Applicant: PILLAR CORPORATION, Osaka (JP)

(72) Inventors: Akira NAKATSU, Osaka-shi (JP); Kentaro WATANABE, Osaka-shi (JP); Yusuke NATSUHARA, Osaka-shi (JP)

(73) Assignee: PILLAR CORPORATION, Osaka (JP)

(21) Appl. No.: 19/046,059

(22) Filed: Feb. 5, 2025

(30) Foreign Application Priority Data
Feb. 5, 2024 (JP) 2024-015638

(51) Int. Cl. G01N 27/22; G01N 27/02; G01N 27/24; G01R 27/26

(52) U.S. Cl. CPC G01N 27/221; G01N 27/023; G01N 27/228; G01N 27/24; G01R 27/267

(57) ABSTRACT

To detect the amount of degradation substance contained in oil.

The present oil state detection apparatus includes an oscillation circuit having a coil and a capacitor and a detection device. Any one of the coil or the capacitor is immersed in oil. The detection device detects the amount of degradation substance contained in the oil based on the value of change in the oscillatory frequency of the oscillation circuit in a predetermined period.

### BACKGROUND

The present disclosure relates to an oil state detection apparatus that detects the amount of degradation substance contained in oil.

Conventionally, there has been a method of determining degradation of oil used as lubricant for, e.g., a vehicle or a construction machinery.

For example, in Japanese Utility Model Publication No. H4-34414, a magnet attached to a container housing lubricant adsorbs metal in the lubricant, and the magnetic flux density of the magnet is detected. In this manner, degradation of the lubricant is determined. Moreover, in Japanese Unexamined Patent Publication No. 2003-114206, AC voltage with two types of frequencies is applied between a pair of opposite electrodes of a capacitive sensor immersed in engine oil to measure an interelectrode capacitance for each frequency, and degradation of the engine oil is determined from a dielectric constant and a dielectric constant difference obtained from each interelectrode capacitance.

### SUMMARY

When a vehicle or a construction machinery is in operation, each portion of the vehicle or the construction machinery is abraded due to friction. Thus, the amount of oil degradation substance contained in oil (lubricant) used for, e.g., the vehicle or the construction machinery is detected so that the abrasion state of each portion of the vehicle or the construction machinery and the state of degradation of the oil can be grasped and damage can be prevented in advance. Examples of the degradation substance include metal powder caused due to the abrasion of the vehicle or the construction machinery, and if a certain amount of degradation substance or more is contained in the oil, each portion is mechanically damaged. The examples further include substances related to the degradation of the oil, such as a substance (e.g., water) degrading the oil by itself and a substance (e.g., sludge) caused due to oxidation of the oil. These degradation substances shorten the life of the oil and block performance. These degradation substances are generally made of, e.g., a magnetic substance, a dielectric substance, or a conductor.

A sensor for detecting the degradation substance in the oil may be provided to detect the amount of degradation substance contained in the oil. However, if the sensor is merely provided in the oil, the output value of the sensor is not constant because the degradation substance is not uniformly dispersed in the oil. Thus, the amount of degradation substance cannot be accurately measured.

For these reasons, the present disclosure is intended to provide an oil state detection apparatus capable of detecting, with favorable accuracy, the amount of degradation substance contained in oil.

In order to accomplish the above-described object, an oil state detection apparatus according to one embodiment of the present disclosure includes an oscillation circuit having a coil and a capacitor, and a detection device. Any one of the coil or the capacitor is immersed in oil, and the detection device detects the amount of degradation substance contained in the oil based on the value of change in the oscillatory frequency of the oscillation circuit in a predetermined period.

According to this configuration, the detection device detects the amount of degradation substance contained in the oil based on the value of change in the oscillatory frequency of the oscillation circuit in a predetermined period. The degradation substance in the oil is not fully dissolved in the oil, and therefore, there are a region where much degradation substance is contained in the oil and a region where not much degradation substance is contained in the oil. As the amount of degradation substance in the oil increases, a difference between the amount of degradation substance in the region where much degradation substance is contained and the amount of degradation substance in the region where not much degradation substance is contained increases. Thus, the amount of degradation substance contained in the oil is detected based on the value of change in the oscillatory frequency of the oscillation circuit in the predetermined period, and in this manner, the amount of degradation substance contained in the oil can be detected with favorable accuracy.

According to the present disclosure, the amount of degradation substance contained in the oil can be detected with favorable accuracy.

### BRIEF DESCRIPTION OF THE DRAWINGS

FIG. 1 is a block diagram illustrating an oil state detection apparatus according to an embodiment.

FIGS. 2A and 2B are graphs illustrating a chronological change in the value of a tuning voltage V according to the embodiment.

FIG. 3 is a graph illustrating a relationship between the range of change in the tuning voltage V and the amount of magnetic substance contained in oil according to the embodiment.

FIG. 4 is a graph illustrating a chronological change in the value of the tuning voltage V due to degradation of the oil according to the embodiment.

FIG. 5 is a graph illustrating a chronological change in the value of the tuning voltage V according to the embodiment in a case where a rapid change in the value of the tuning voltage V occurs.

FIGS. 6A and 6B are graphs illustrating a change in the value of the tuning voltage V over time and a difference in the tuning voltage V according to a variation.

FIG. 7 is a graph illustrating an integration value of a difference between the maximum value and minimum value of the tuning voltage V according to the variation.

### DETAILED DESCRIPTION

Hereinafter, an embodiment of the present disclosure will be described in detail with reference to the drawings. The following description of the preferred embodiment is merely an example in nature, and is not intended to limit the scope of the present disclosure and the application or use thereof.

### EMBODIMENT

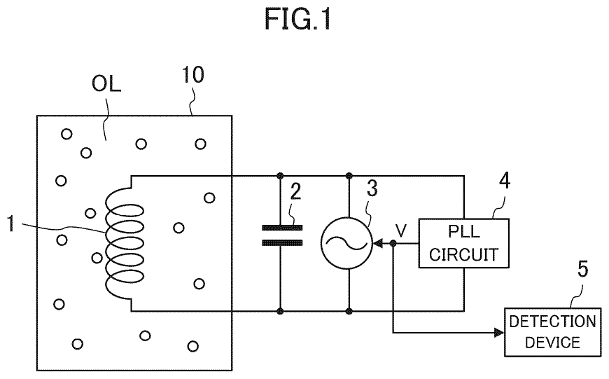

FIG. 1 is a block diagram illustrating an oil state detection apparatus according to the embodiment. As illustrated in FIG. 1, this oil state detection apparatus includes a coil 1 (first coil), a capacitor 2 (first capacitor), an oscillator (e.g., voltage-controlled oscillator (VCO)) 3, a phase-locked loop (PLL) circuit 4, and a detection device 5.

As illustrated in FIG. 1, the coil 1 is disposed inside a case 10 filled with oil OL (lubricant). The case 10 is, for example, an oil pan or an oil tank, and is for circulating the oil OL in a vehicle or a construction machinery. Alternatively, the case 10 is, for example, a gearbox or a transmission case, and is for accumulating the oil OL in a vehicle or a construction machinery. The coil 1 is immersed in the oil OL inside the case 10. Thus, the inductance of the coil 1 changes in accordance with the amount of magnetic substance contained in the oil OL.

Here, the oscillatory frequency F of an oscillation circuit including the coil 1 and the capacitor 2 is represented by the following equation:

$$F = \frac{1}{2 π \sqrt{L \cdot C}} \qquad [ Equation 1 ]$$

where the inductance of the coil 1 is L and the capacity of the capacitor 2 is C.

The PLL circuit 4 inputs a tuning voltage V to the oscillator 3 such that the output frequency of the oscillator 3 satisfies Equation (1).

The detection device 5 detects the amount of magnetic substance (amount of degradation substance) contained in the oil OL according to the tuning voltage V output from the PLL circuit 4. The detection device 5 is, for example, a microcomputer including, e.g., a central processing unit (CPU) and a semiconductor memory.

According to Equation (1) above, as the amount of magnetic substance contained in the oil OL increases, the inductance L of the coil 1 changes (increases or decreases). Thus, the value of the tuning voltage V increases as the amount of magnetic substance contained in the oil OL increases. Accordingly, the PLL circuit 4 increases the tuning voltage V to decrease the output frequency of the oscillator 3 such that the output frequency of the oscillator 3 follows the oscillatory frequency of the oscillation circuit. Thus, the amount of magnetic substance (amount of degradation substance) contained in the oil OL can be detected by detecting the value of the tuning voltage V, i.e., the output frequency of the oscillator 3.

As illustrated in FIG. 1, this oil state detection apparatus includes the coil 1, the capacitor 2, the oscillator 3, the PLL circuit 4, and the detection device 5. Thus, the inductance value of the coil 1 can be decreased by increasing the oscillatory frequency of the oscillation circuit (coil 1 and capacitor 2), for example. Consequently, the oil state detection apparatus can be reduced in size. Note that the oscillator 3 normally includes a semiconductor element, and therefore, the size thereof does not change according to a change in the output frequency.

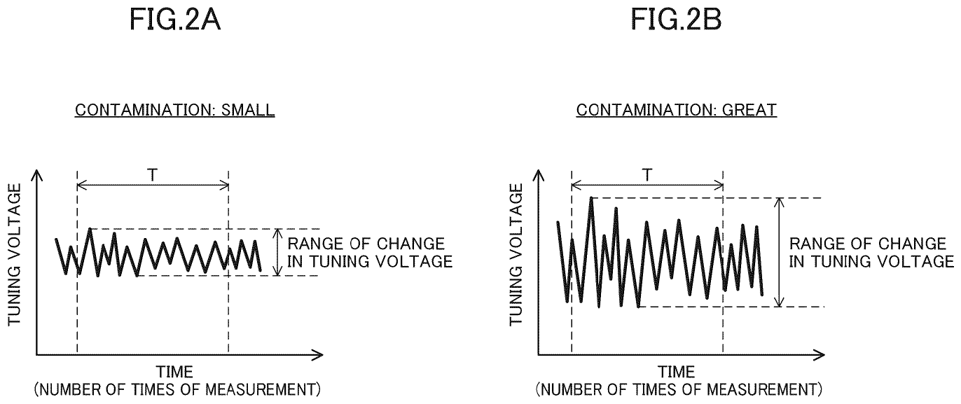

FIGS. 2A and 2B are graphs illustrating a chronological change in the value of the tuning voltage V. Specifically, FIG. 2A illustrates a chronological change in the value of the tuning voltage V in a case of a small amount of magnetic substance in the oil OL, and FIG. 2B illustrates a chronological change in the value of the tuning voltage V in a case of a great amount of magnetic substance in the oil OL.

As illustrated in FIGS. 2A and 2B, the value of the tuning voltage V is not constant, but changes over time. This is because the degradation substance (magnetic substance) is not fully dissolved in the oil OL and there are a region where much degradation substance is contained in the oil OL and a region where not much degradation substance is contained in the oil OL. That is, the degradation substance is not uniformly dispersed in the oil OL, and for this reason, the value of the tuning voltage V changes.

Thus, in the present embodiment, the detection device 5 detects the amount of degradation substance (magnetic substance) in the oil OL according to the range of change (the value of change) in the tuning voltage V. The range of change is calculated from a difference between the maximum value and the minimum value of the tuning voltage in a predetermined period T.

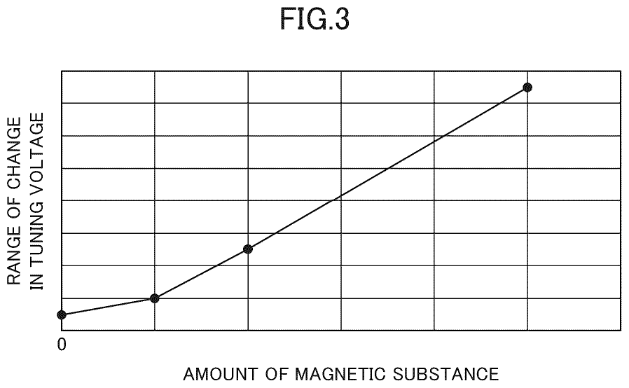

FIG. 3 is a graph illustrating a relationship between the range of change in the tuning voltage V and the amount of magnetic substance contained in the oil OL.

As illustrated in FIG. 3, the range of change in the value of the tuning voltage V increases as the amount of magnetic substance in the oil OL increases. This is because as the amount of magnetic substance in the oil OL increases, a difference between the amount of degradation substance in the region where much degradation substance (magnetic substance) is contained and the amount of degradation substance in the region where not much degradation substance is contained increases. Thus, the amount of degradation substance contained in the oil OL is detected based on the range of change in the tuning voltage V, and in this manner, the amount of degradation substance contained in the oil OL can be detected with favorable accuracy.

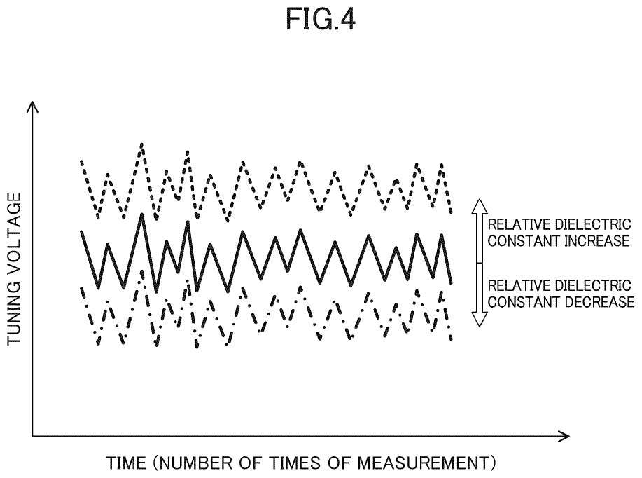

FIG. 4 is a graph illustrating a chronological change in the value of the tuning voltage V due to degradation of the oil OL. Specifically, in FIG. 4, a chronological change in the value of the tuning voltage V before the degradation of the oil OL is indicated by a solid line, and a chronological change in the value of the tuning voltage V after the degradation of the oil OL is indicated by a dashed line and a dash-dotted line.

The oil OL is degraded over time due to, e.g., oxidation, and therefore, the relative dielectric constant thereof changes. Thus, the value of the tuning voltage V itself increases or decreases as a whole due to the degradation of the oil, but the range of change in the tuning voltage V does not change much due to the degradation of the oil. For this reason, the amount of magnetic substance contained in the oil OL is detected based on the range of change in the tuning voltage V, and in this manner, the amount of magnetic substance contained in the oil OL can be detected with favorable accuracy.

Note that the detection device 5 may perform the following processing in a case where a rapid change in the value of the tuning voltage V occurs.

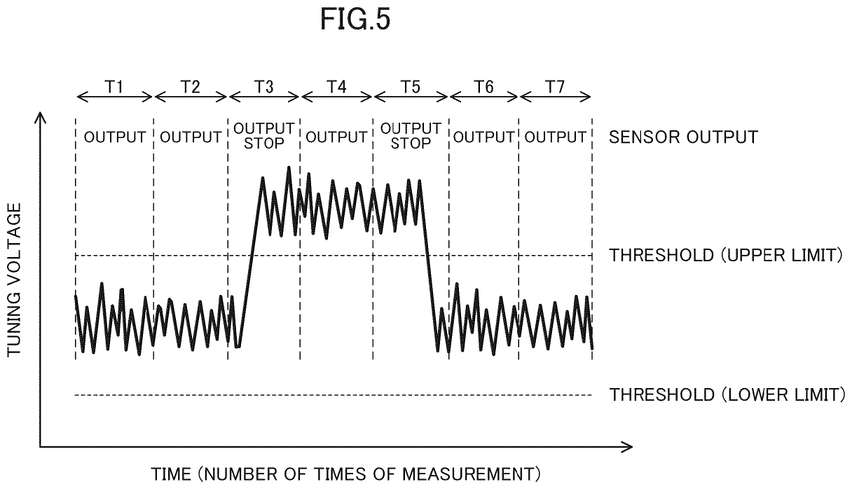

FIG. 5 is a graph illustrating a chronological change in the value of the tuning voltage V in the case where the rapid change in the value of the tuning voltage V occurs.

As illustrated in FIG. 5, the rapid change in the value of the tuning voltage V has occurred in predetermined periods T3, T5. Considering the range of change in the value of the tuning voltage V in, e.g., predetermined periods T1, T2, the amount of magnetic substance is great only in the predetermined periods T3, T5, and for this reason, the accuracy of the detection of the amount of magnetic substance is lowered. Thus, the detection device 5 (sensor) does not output the result of the detection of the amount of magnetic substance in these predetermined periods in a case where the range of change in the value of the tuning voltage V does not fall within a threshold range.

In the example of FIG. 5, the threshold is the preset upper limit or lower limit of the value of the tuning voltage V. As another example of FIG. 5, the threshold may be set based on the value of change in the value of the tuning voltage V in the previous predetermined period. In this case, the threshold may be set to a value obtained by adding a predetermined value to the maximum value of the tuning voltage V in the previous predetermined period (or by subtracting a predetermined value from the minimum value).

### (Variation)

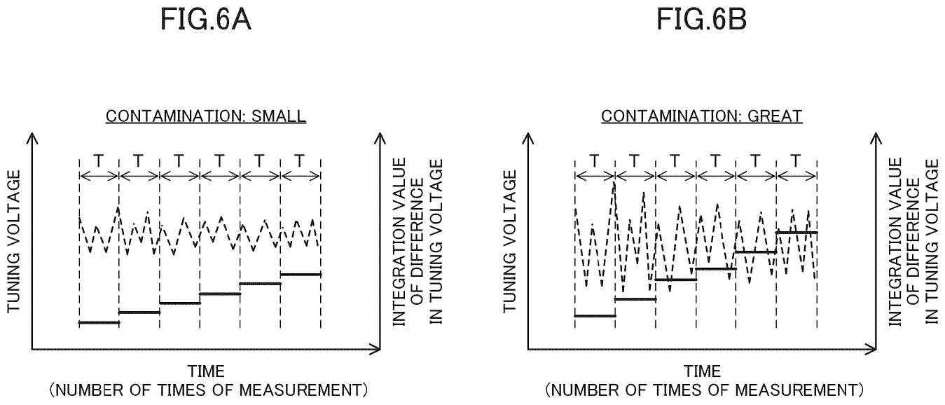

FIGS. 6A and 6B are graphs illustrating the change in the value of the tuning voltage V over time and the difference in the value of the tuning voltage V. Specifically, in FIGS. 6A and 6B, the change in the value of the tuning voltage V over time is indicated by a dashed line, and the integration value of the difference between the maximum value and the minimum value of the tuning voltage V in each predetermined period is indicated by a solid line. Moreover, FIG. 6A illustrates a case where the amount of magnetic substance in the oil OL is small, and FIG. 6B illustrates a case where the amount of magnetic substance in the oil OL is great.

As a result of comparison between FIGS. 6A and 6B, in the case of the great amount of magnetic substance in the oil OL, the integration value of the difference between the maximum value and the minimum value of the tuning voltage V increases over time.

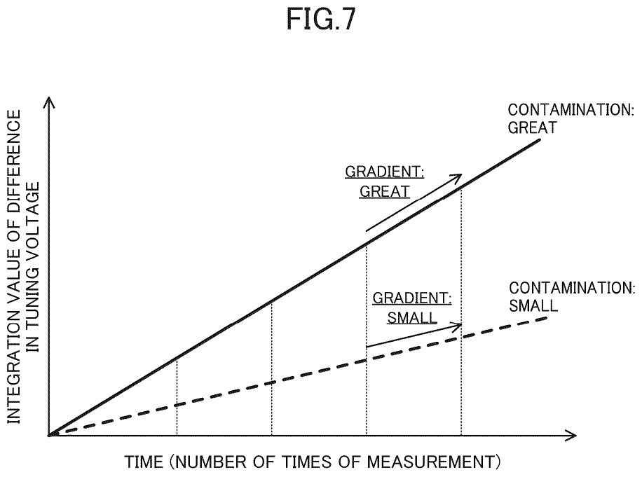

FIG. 7 is a graph illustrating the integration value of the difference between the maximum value and the minimum value of the tuning voltage V. In FIG. 7, the integration value in the case of the small amount of magnetic substance in the oil OL is indicated by a dashed line, and the integration value in the case of the great amount of magnetic substance in the oil OL is indicated by a solid line.

As illustrated in FIG. 7, when the integration value of the difference between the maximum value and the minimum value of the tuning voltage V over time is plotted on the graph, the gradient of the graph is greater in the case of the great amount of magnetic substance in the oil OL, whereas the gradient of the graph is smaller in the case of the small amount of magnetic substance in the oil OL. As described above, the amount of magnetic substance in the oil OL may be detected based on the integration value of the difference between the maximum value and the minimum value of the tuning voltage V. Particularly, in the case of the small amount of magnetic substance in the oil OL, the range of change in the value of the tuning voltage V is small. Thus, the above-described difference is detected for each predetermined period, so that the accuracy of the detection of the amount of magnetic substance in the oil OL can be enhanced even in the case of the small amount of magnetic substance in the oil OL.

The embodiment has been described above as an example of the technique disclosed herein. However, the technique of the present disclosure is not limited to above, and can also be applied to embodiments with modifications, substitutions, additions, omissions, and the like, as appropriate.

Note that in the above-described embodiment and variation, the detection device 5 detects the oscillatory frequency (tuning voltage V) of each oscillation circuit, but a configuration other than the oscillator and the PLL circuit may detect the oscillatory frequency of each oscillation circuit. The present oil state detection apparatus may have any configuration as long as the oil state detection apparatus can detect the oscillatory frequency (tuning voltage V) of the oscillation circuit.

In the above-described embodiment and variation, the detection device includes the PLL circuit, but the present disclosure is not limited thereto. For example, the detection device may include, for example, an arithmetic circuit that analyzes an input frequency or an analysis circuit that lowers an input frequency to analyze the frequency, instead of the PLL circuit 4.

In the above-described embodiment and variation, the capacitor 2 may be immersed in the oil OL, instead of the coil 1. With this configuration, in each variation of the embodiment, the amount of dielectric substance (amount of degradation substance) contained in the oil OL can be detected.

In the above-described embodiment and variation, the case where the value of change in the oscillatory frequency of the oscillation circuit in the predetermined period is the range of change in the tuning voltage V in the predetermined period T has been described as an example, but the present disclosure is not limited thereto. For example, the value of change in the oscillatory frequency of the oscillation circuit in the predetermined period may be the intermediate value, average, or standard deviation of the tuning voltage V in the predetermined period T.

The oil state detection apparatus of the present disclosure can detect the amount of degradation substance, such as a magnetic substance or a dielectric substance, contained in oil used as lubricant for, e.g., a construction machinery or a vehicle.

What is claimed is:

1. An oil state detection apparatus comprising:
an oscillation circuit including a coil and a capacitor; and
a detection device,
wherein any one of the coil or the capacitor is immersed in oil, and
the detection device detects an amount of degradation substance contained in the oil based on a value of change in an oscillatory frequency of the oscillation circuit in a predetermined period.

2. The oil state detection apparatus of claim 1, wherein
the detection device does not output a result of detection of the amount of degradation substance in the predetermined period in a case where the value of change does not fall within a range of threshold.

3. The oil state detection apparatus of claim 2, wherein
the threshold is set based on the value of change in a predetermined period before the predetermined period.

4. The oil state detection apparatus of claim 1, wherein
the oscillation circuit includes an oscillator and a phase-locked loop (PLL) circuit, and
the PLL circuit inputs a tuning voltage to the oscillator such that an output frequency of the oscillator is coincident with the oscillatory frequency.

5. The oil state detection apparatus of claim 4, wherein
the value of change is a difference between a maximum value and a minimum value of the tuning voltage in the predetermined period, and
the detection device detects the amount of degradation substance contained in the oil based on the difference between the maximum value and the minimum value of the tuning voltage for each predetermined period.

6. The oil state detection apparatus of claim 4, wherein
the value of change is at least any one of a range of change in the tuning voltage or an intermediate value, an average, or a standard deviation of the tuning voltage in the predetermined period.
